(19) United States
(12) Patent Application Publication
(10) Pub. No.: US 2010/0255344 A1
(43) Pub. Date: Oct. 7, 2010

(54) METHOD OF MANUFACTURING THIN FILM DEVICE AND THIN FILM DEVICE MANUFACTURED USING THE SAME

(75) Inventors: Boum Seock Kim, Suwon (KR); Yongsoo Oh, Seongnam (KR); Sang Jin Kim, Suwon (KR); Hwan-Soo Lee, Seoul (KR)

Correspondence Address: MCDERMOTT WILL & EMERY LLP, 18191 VON KARMAN AVE., SUITE 500, IRVINE, CA, 92612-7108, US

(73) Assignee: SAMSUNG ELECTRO-MECHANICS CO., LTD., Suwon (KR)

(21) Appl. No.: 12/545,658

(22) Filed: Aug. 21, 2009

(30) Foreign Application Priority Data
Apr. 6, 2009 (KR) 10-2009-0029520

(51) Int. Cl. B32B 9/00; H01L 21/28

(52) U.S. Cl. 428/697; 438/3; 257/E21.158

(57) ABSTRACT

There is provided a method of manufacturing a thin film device and a thin film device manufactured using the same. The method includes forming a sacrificial layer using a first oxide having a perovskite structure on a preliminary substrate; forming an electrode layer using a second oxide having a perovskite structure on the sacrificial layer; forming a thin film laminate on the electrode layer; bonding a permanent substrate onto the thin film laminate; decomposing the sacrificial layer by irradiating a laser onto the preliminary substrate; and separating the preliminary substrate from the electrode layer. During a laser lift-off process, degradation of properties caused by oxygen diffusion can be prevented. Since the electrode layer has thermal conductivity lower than an existing metal electrode, heat emission can be considerably reduced and the sacrificial layer can be easily decomposed by heat accumulation. Therefore, a thin film device having excellent properties can be manufactured.

### CROSS-REFERENCE TO RELATED APPLICATIONS

This application claims the priority of Korean Patent Application No. 2009-0029520 filed on Apr. 6, 2009, in the Korean Intellectual Property Office, the disclosure of which is incorporated herein by reference.

### BACKGROUND OF THE INVENTION

1. Field of the Invention

The present invention relates to a method of manufacturing a thin film device and a thin film device manufactured using the same, and more particularly, to a method of manufacturing a thin film device using a simplified laser lift-off process and a thin film device having excellent properties.

2. Description of the Related Art

In general, a thin film transfer technique has been widely used in electronic devices such as a thin film transistor (TFT) and optical devices such as an organic EL device.

The thin film transfer technique generally refers to a technique that forms a thin film on a preliminary substrate and then transfers the thin film onto a permanent substrate to thereby manufacture a desired thin film device. This thin film transfer technique can be of great use when the conditions of a substrate used to form a film are different from those of a substrate used in a thin film device.

For example, even though the formation of a thin film serving as a functional unit requires a relatively high-temperature process, if a substrate used in a thin film device has low thermal resistance, a low glass transition temperature or a low melting point, the thin film transfer technique can be advantageously applied. Particularly, the thin film transfer technique can be very advantageously applied to flexible thin film devices.

Since a flexible device needs to have flexibility, an organic substrate such as a polymer is used and an organic thin film serving as a functional unit is disposed on the top of the organic substrate. However, since it is difficult to ensure the high performance of the functional unit formed of the organic thin film, it is necessary to form a functional unit of the flexible device by the use of an inorganic material. In this case, since it is difficult to apply a high-temperature deposition process directly to a flexible substrate formed of an organic material, the thin film transfer technique that forms a thin film formed of an inorganic material such as a semiconductor on another preliminary substrate and then transfers the thin film onto an organic substrate is used.

Meanwhile, the thin film transfer technique generally requires a cut & paste process. More specifically, in order to separate a thin film device from a donor substrate, an acceptor substrate is laminated and then the thin film device is separated from the donor substrate by the use of a laser lift-off process. However, the laser lift-off process needs a sacrificial layer to be removed by a laser, and a device material satisfying desired requirements needs to be formed on the sacrificial layer.

### SUMMARY OF THE INVENTION

An aspect of the present invention provides a method of a thin film device for simplifying the entire process and obtaining a thin film device having excellent properties.

According to an aspect of the present invention, there is provided a method of manufacturing a thin film device, the method including: forming a sacrificial layer using a first oxide having a perovskite structure on a preliminary substrate; forming an electrode layer using a second oxide having a perovskite structure on the sacrificial layer; forming a thin film laminate on the electrode layer; bonding a permanent substrate onto the thin film laminate; decomposing the sacrificial layer by irradiating a laser onto the preliminary substrate; and separating the preliminary substrate from the electrode layer.

The preliminary substrate may have a glass transition temperature or a melting point higher than the temperature applied to the formation of the thin film laminate.

The sacrificial layer may have an energy band gap lower than an energy band gap of the preliminary substrate.

The first oxide may be one or more oxides selected from the group consisting of LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, (Ca,Sr)TiO₃, CaTiO₃, PbTiO₃, Pb(Zr,Ti)O₃, (Pb,La)(Zr,Ti)O₃, (Ba,Sr)TiO₃, BaTiO₃, KTaO₃ and (Bi,La)FeO₃.

The second oxide may be BSR.

The thin film laminate may include at least one of a dielectric layer, a magnetic layer, an insulating layer, and a conducting layer.

The thin film laminate may include one or more dielectric layers selected from the group consisting of PZT, PLZT, SBT, SBTN, BIT, BLT, PMN-PT and PZN-PT.

The permanent substrate may have a glass transition temperature or a melting point lower than the temperature applied to the formation of the thin film laminate. The permanent substrate may be a flexible substrate.

The thin film device may be one of a thin film transistor (TFT), a piezo electric element, a biosensor, a solar cell and an optical sensor.

According to another aspect of the present invention, there is provided a thin film device, including a permanent substrate; a thin film laminate formed on the permanent substrate; and an electrode layer formed on the thin film laminate by the use of a second oxide having a perovskite structure.

The permanent substrate may have a glass transition temperature or a melting point lower than the temperature applied to the formation of the thin film laminate. The permanent substrate may be a flexible substrate.

The thin film laminate may include at least one of a dielectric layer, a magnetic layer, an insulating layer, and a conducting layer.

The thin film laminate may include one or more dielectric layers selected from the group consisting of PZT, PLZT, SBT, SBTN, BIT, BLT, PMN-PT and PZN-PT.

The electrode layer may include BSR.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 1F are schematic cross-sectional views illustrating a series of processes in a method of manufacturing a thin film device according to an exemplary embodiment of the present invention; and

FIG. 2 is an enlarged cross-sectional view schematically illustrating a part of boundary surface between a sacrificial layer and an electrode layer in a method of manufacturing a thin film device according to another exemplary embodiment of the present invention.

### DETAILED DESCRIPTION OF THE PREFERRED EMBODIMENT

Exemplary embodiments of the present invention will now be described in detail with reference to the accompanying drawings.

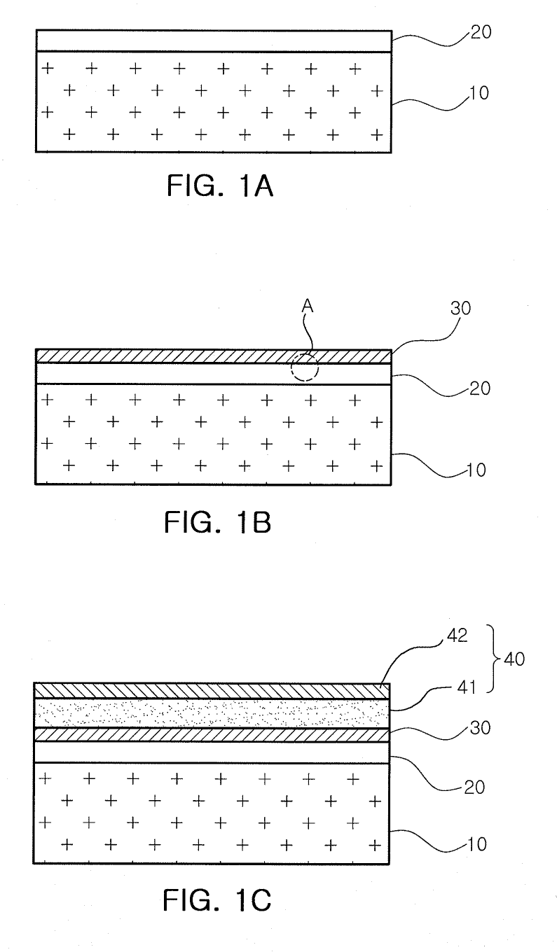

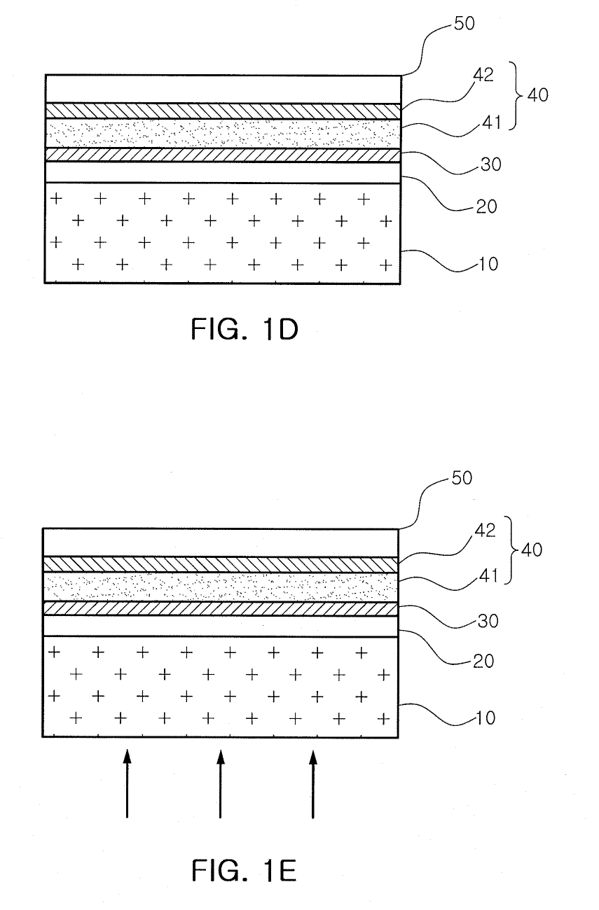

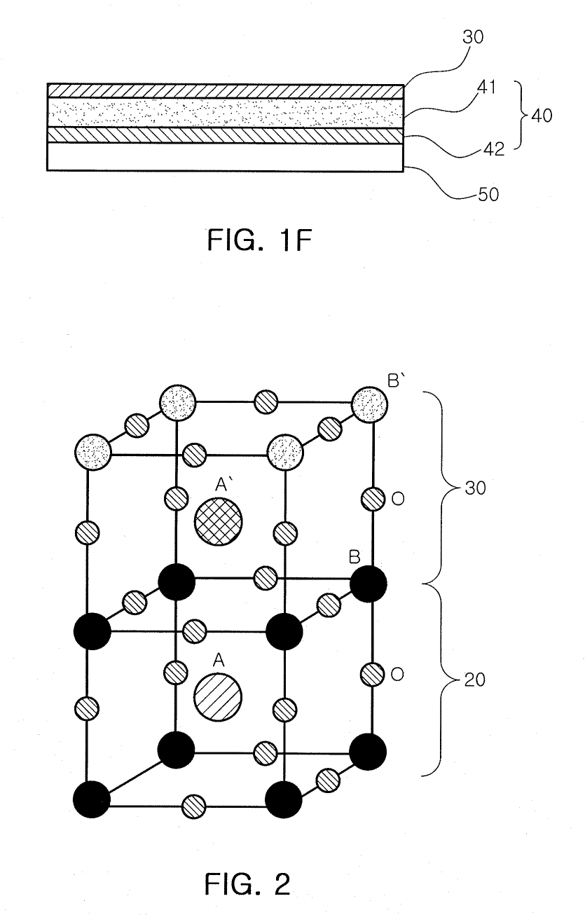

FIGS. 1A through 1F are schematic cross-sectional views illustrating a series of processes in a method of manufacturing a thin film device according to an exemplary embodiment of the present invention.

First of all, as illustrated in FIG. 1A, a preliminary substrate 10 is prepared, and then a sacrificial layer 20 is deposited on the preliminary substrate 10 by the use of a first oxide having a perovskite structure (ABO₃). The preliminary substrate 10 may be transmitted by the laser and have a greater band gap than the energy corresponding to a wavelength of the laser.

The preliminary substrate 10 may be suitable for forming a thin film serving as a particular functional device. For example, when a desired thin film requires high-temperature deposition conditions, the preliminary substrate may be formed of a material having thermal resistance. More specifically, the preliminary substrate 10 may have a glass transition temperature or a melting point higher than the temperature applied to the formation of a thin film laminate.

For example, a rigid substrate, such as Al₂O₃, MgO, SiO₂, quartz, glass and ZrO₂, may be used.

The sacrificial layer 20 may be decomposed by which its crystalline structure is amorphized by laser irradiation. The sacrificial layer 20 may be formed of the first oxide having an energy band gap lower than an energy band gap of the preliminary substrate 10 and having the perovskite structure (ABO₃). The term “first oxide” as used throughout this specification may be understood to be a material used in forming the sacrificial layer 20.

There is no particular limitation in the category of first oxides. For example, the first oxide may include one or more oxides selected from the group consisting of LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, (Ca,Sr)TiO₃, CaTiO₃, PbTiO₃, Pb(Zr,Ti)O₃, (Pb,La)(Zr,Ti)O₃, (Ba,Sr)TiO₃, BaTiO₃, KTaO₃ and (Bi,La)FeO₃. Here, it is desirable to include Pb(Zr,Ti)O₃ or (Pb,La)(Zr,Ti)O₃.

The sacrificial layer 20 may be deposited by the use of a sol-gel method, an RF sputtering method, or an MOCVD method.

Next, as illustrated in FIG. 1B, an electrode layer 30 is formed on the sacrificial layer by the use of a second oxide having a perovskite structure (A′B′O₃). The term “second oxide” as used throughout this specification may be understood to be a material used in forming the electrode layer 30.

There is no particular limitation in the category of second oxides. For example, the second oxide may be BSR [(BaₓSr₁₋ₓ)RuO₃].

The electrode layer 30 may be typically formed by the use of PVD, CVD, or ALD.

The electrode layer 30 may be formed of an oxide having a perovskite structure (A′B′O₃) like the sacrificial layer 20, so the sacrificial layer 20 and the electrode layer 30 have a similar lattice constant.

FIG. 2 illustrates an enlarged A area of FIG. 1B. FIG. 2 is an enlarged cross-sectional view schematically illustrating a boundary surface between the sacrificial layer 20 and the electrode layer 30. Referring to FIG. 2, an oxide used in forming the sacrificial layer 20 and the electrode layer 30 has a perovskite structure and a similar lattice constant.

More specifically, the electrode layer 30 is formed of BSR whose lattice constant ranges from 0.397 nm to 0.409 nm according to the ratio of Ba to Sr and the sacrificial layer 20 is formed of PZT whose lattice constant is approximately 0.404 nm. Accordingly, in the process of a laser lift-off to remove the sacrificial layer, the degradation of properties caused by oxygen diffusion can be prevented, and the emission of heat can be considerably reduced relative to other metallic materials. Also, the crystallinity of a thin film laminate formed on the electrode layer 30 can be improved.

After that, as illustrated in FIG. 1C, a thin film laminate 40 is formed on the electrode layer 30. The thin film laminate according to the embodiment of the present invention may be formed in a plurality of layers according to desired thin film device. More specifically, the thin film laminate serving as a particular functional device may include a dielectric layer, a magnetic layer, an insulating layer, or a conducting layer.

There is no particular limitation in the category of thin film laminates. For example, the thin film laminate may include one or more dielectric layers selected from the group consisting of PZT (Lead zirconium titanate: Pb(ZrₓTi₁₋ₓ)O₃, 0<x<1), PLZT (lanthanum-doped lead zirconate titanate: Pb_{y}La_{1-y}(ZrₓTi₁₋ₓ)O₃), SBT (Strontium bismuth tantalite: SrBi₂Ta₂O₉), SBTN(Strontium barium tantalate noibate), BIT (bismuth titanate Bi₄Ti₃O₁₂), BLT (bismuth lanthanum titanate: Bi₄₋ₓLaₓTi₃O₁₂), PMN-PT (Lead magnesium niobate-lead titanate) and PZN-PT (Lead zinc niobate-lead titanate). Here, it is desirable to include PZT or PLZT.

A type of thin film device according to the embodiment of the present invention may be variable according to the formation of the thin film laminate. Preferably, the thin film device may be a flexible device. For another example, it may be a thin film transistor (TFT), a piezo electric element, a biosensor or a photoelectric conversion element such as a solar cell and an optical sensor. However, the invention is not limited thereto.

In this embodiment, the thin film laminate 40 takes an example to successively form a dielectric layer 41 and an electrode layer 42. The dielectric layer 41 may be formed by the use of a sol-gel coating process and the electrode layer 42 may be deposited by the use of a sputtering process. The electrode layer 42 may be formed of a metal electrode or an oxide having a perovskite structure.

The thin film laminate 40 has excellent crystallinity since it is deposited on the electrode layer 30 formed of the first oxide having the perovskite structure. That is, the crystallinity is improved relative to the deposition on the metal electrode according to the related art, and the properties of a resultant thin film device are improved. When the thin film laminate 40 includes a dielectric layer formed of PZT or PLZT, it has the same structure and the similar lattice constant as the electrode layer 30, thereby obtaining a device having improved properties.

When the thin film laminate 40 is deposited, it is bonded to the electrode layer 30 through heat treatment.

Then, as illustrated in FIG. 1D, a permanent substrate 50 is bonded onto the thin film laminate 40. The term “permanent substrate” as used throughout this specification may be understood to be a substrate provided as an object of transfer and used in constructing a thin film device.

The permanent substrate 50 may have a glass transition temperature or a melting point lower than the temperature applied to the formation of the thin film laminate. The permanent substrate 50 may be a flexible substrate formed of a polymer.

Then, as illustrated in FIG. 1E, a laser is irradiated onto the preliminary substrate 10 in a direction in which the electrode layer 30 is not formed. When the laser is irradiated onto the preliminary substrate 10, the sacrificial layer 20 formed on the preliminary substrate is decomposed by which its crystalline structure is amorphized.

There is no particular limitation in laser types and laser irradiating methods. A laser may have energy between band gaps of the preliminary substrate 10 and the sacrificial layer 20. For example, an excimer laser (126 nm, 146 nm, 157 nm, 172 nm, 175 nm, 193 nm, 248 nm, 282 nm, 308 nm, 351 nm, 222 nm, 259 nm) or an Nd-YAG laser (266 nm, 355 nm) may be used. When the sacrificial layer 20 is formed of PLZT, the excimer laser of 248 nm may be used.

As described above, the sacrificial layer 20 and the electrode layer 30 formed of the oxide having the perovskite structure are similar in terms of structure and lattice constant. Since they have thermal conductivity lower than a metallic material, they can lower the thermal conductivity during the laser lift-off. Accordingly, the amorphization of the sacrificial layer 20 can be accelerated. That is, the decomposition of the sacrificial layer 20 can be accelerated by heat accumulation and the thin film can be easily separated.

When the sacrificial layer 20 is decomposed by the laser irradiation, the preliminary substrate 10 is separated from the electrode layer 30. Accordingly, as illustrated in FIG. 1F, a thin film device including the electrode layer 30, the thin film laminate 40, and the permanent layer 50 is manufactured.

A method of manufacturing a thin film device according to an embodiment of the present invention may be applied to a variety of thin film devices. Even though the formation of a thin film laminate requires a relatively high-temperature process, if a substrate used in a thin film device has low thermal resistance, a low glass transition temperature or a low melting point, the method of manufacturing the thin film device according to the embodiment of the present invention can be advantageously applied. Particularly, it can be very advantageously applied to flexible thin film devices.

According to another embodiment of the present invention as illustrated in FIG. 1F, there is provided a thin film device including a permanent substrate 50, a thin film laminate 40 formed on the permanent substrate, and an electrode layer 30 formed on the thin film laminate by the use of a second oxide having a perovskite structure. The thin film device may be formed by the aforementioned method, and concrete characteristics of the permanent substrate 50, the thin film laminate 40 and the electrode layer 30 are the same as aforementioned.

The thin film device may be manifested in a variety of forms according to various types of thin film laminate. Preferably, it may be a flexible device. For another example, it may be a thin film transistor (TFT), a piezo electric element, a biosensor, or a photoelectric conversion element such as a solar cell and an optical sensor. However, the invention is not limited thereto.

As set forth above, in a method of manufacturing a thin film device according to an exemplary embodiment of the present invention, a sacrificial layer and an electrode layer are formed of an oxide having a perovskite structure, thereby being able to prevent the degradation of properties caused by oxygen diffusion during a laser lift-off process. Also, since the electrode layer has lower thermal conductivity than an existing metal electrode, the emission of heat can be considerably reduced and the amorphization of the sacrificial layer can be accelerated. Consequently, a thin film device having excellent properties can be manufactured.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a thin film device, comprising:
forming a sacrificial layer using a first oxide having a perovskite structure on a preliminary substrate;
forming an electrode layer using a second oxide having a perovskite structure on the sacrificial layer;
forming a thin film laminate on the electrode layer;
bonding a permanent substrate onto the thin film laminate;
decomposing the sacrificial layer by irradiating a laser onto the preliminary substrate; and
separating the preliminary substrate from the electrode layer.

2. The method of claim 1, wherein the preliminary substrate has a glass transition temperature or a melting point higher than a temperature applied to a formation of the thin film laminate.

3. The method of claim 1, wherein the sacrificial layer has an energy band gap lower than an energy band gap of the preliminary substrate.

4. The method of claim 1, wherein the first oxide includes one or more oxides selected from the group consisting of LaMnO₃, LaAlO₃, MgSiO₃, (Ca,Na)(Nb,Ti,Fe)O₃, (Ce,Na,Ca)₂(Ti,Nb)₂O₆, NaNbO₃, SrTiO₃, (Na,La,Ca)(Nb,Ti)O₃, Ca₃(Ti,Al,Zr)₉O₂₀, (Ca,Sr)TiO₃, CaTiO₃, PbTiO₃, Pb(Zr,Ti)O₃, (Pb,La)(Zr,Ti)O₃, (Ba,Sr)TiO₃, BaTiO₃, KTaO₃ and (Bi,La)FeO₃.

5. The method of claim 1, wherein the second oxide is BSR.

6. The method of claim 1, wherein the thin film laminate includes at least one of a dielectric layer, a magnetic layer, an insulating layer, and a conducting layer.

7. The method of claim 1, wherein the thin film laminate includes one or more dielectric layers selected from the group consisting of PZT, PLZT, SBT, SBTN, BIT, BLT, PMN-PT and PZN-PT.

8. The method of claim 1, wherein the permanent substrate has a glass transition temperature or a melting point lower than a temperature applied to a formation of the thin film laminate.

9. The method of claim 1, wherein the permanent substrate is a flexible substrate.

10. The method of claim 1, wherein the thin film device is one of a thin film transistor (TFT), a piezo electric element, a biosensor, a solar cell and an optical sensor.

11. A thin film device, comprising:
a permanent substrate;
a thin film laminate formed on the permanent substrate; and
an electrode layer formed on the thin film laminate by the use of a second oxide having a perovskite structure.

12. The thin film device of claim 11, wherein the permanent substrate has a glass transition temperature or a melting point lower than a temperature applied to a formation of the thin film laminate.

13. The thin film device of claim 11, wherein the permanent substrate is a flexible substrate.

14. The thin film device of claim 11, wherein the thin film laminate includes at least one of a dielectric layer, a magnetic layer, an insulating layer, and a conducting layer.

15. The thin film device of claim 11, wherein the thin film laminate includes one or more dielectric layers selected from the group consisting of PZT, PLZT, SBT, SBTN, BIT, BLT, PMN-PT and PZN-PT.

16. The thin film device of claim 11, wherein the electrode layer includes BSR.
